(19) United States
(12) Patent Application Publication
(10) Pub. No.: US 2025/0370025 A1
(43) Pub. Date: Dec. 4, 2025

(54) METHOD AND DEVICE FOR FORECASTING UPCOMING FAULTS IN POWER SYSTEMS

(71) Applicant: Eneryield AB, 412 92 Göteborg (SE)

(72) Inventors: Ebrahim BALOUJI, Mölnlycke (SE); Karl BÄCKSTRÖM, Göteborg (SE); Viktor OLSSON, Göteborg (SE)

(21) Appl. No.: 18/874,968

(22) PCT Filed: Jun. 30, 2023
(86) PCT No.: PCT/EP2023/068036

§ 371 Date: Dec. 13, 2024

(30) Foreign Application Priority Data
Jun. 30, 2022 (SE) 2250814-7

(51) Int. Cl. G01R 31/08; H02J 13/00

(52) U.S. Cl. CPC G01R 31/088; H02J 13/00002

(57) ABSTRACT

The present disclosure relates to a computer-implemented method for predicting upcoming conductor faults causing failure in components of an electrical power system, the method comprising steps of obtaining data from said components of said electrical power system. Further comprising extracting features and identifying patterns from anomalies in said data. Further, comprising classifying said anomalies based on said patterns so to sort anomalies into classes. Moreover, comprising identifying anomalies and providing a prediction indicative of when at least one upcoming anomaly of a specific class will occur. Furthermore, the method comprises determining a likelihood of that at least one of said upcoming anomalies causes failure in said electrical power system and providing information of said prediction accessible to a user.

### TECHNICAL FIELD

The present disclosure relates to a method and an electronic device for predicting upcoming conductor faults causing failure in components of an electrical power system.

### BACKGROUND

Generally, electrical power systems such as power grids, are operated in a reactive manner. Thus, operators and users of such system would benefit by being able to act with a proactive approach rather than a reactive approach.

Accordingly, in most of the existing systems, users and operators can only be aware of a fault as it already has happened. Meaning, most of the existing solutions only log what already occurred. Hence, gathered data is stacked up without being properly utilized. By being able to properly predict future faults of electrical power systems or the components thereof, there will be many saved hours of downtime and wasted energy.

Even though there are some prior art that are directed to identifying anomalies in electrical power systems, there are none that are directed to predicting upcoming faults causing failure in electrical power systems. By being able to predict when an upcoming fault causing failure will occur, maintenance could be planned accordingly, and the system can be used at least until shortly before the predicted fault will occur.

Based on the above, there is in the present art room for improvements in order to have methods and devices that allow for predicting upcoming faults causing failure in electrical power systems.

Thus, there is room for methods and devices in the present art to explore the domain to providing improved methods and devices for predicting upcoming conductor faults causing failure in components of an electrical power system. Specifically, the methods and devices should provide predictions that are accurate.

Even though some currently known solutions work well in some situations it would be desirable to provide methods and devices that specifically fulfils requirements relating to prediction accuracy.

### SUMMARY

It is therefore an object of the present disclosure to provide an electronic device and a method to mitigate, alleviate or eliminate one or more of the above-identified deficiencies and disadvantages.

This object is achieved by means of a method, a computer-readable storage medium and an electronic device as defined in the appended claims.

The present disclosure is at least partly based on the insight that by providing improved method, device and computer readable storage medium, upcoming conductor faults causing failure in an electrical power system can be accurately predicted so that users/operators thereof can timely act, e.g. by maintenance, thereby saving costs and downtime of the system and/or increasing life length of system hardware and energy efficiency.

The present disclosure provides a computer-implemented method for predicting upcoming conductor faults causing failure (i.e. that may cause failure at a future point in time) in components of an electrical power system. The method comprising the steps of obtaining data (e.g. present data and historical data) from said components of said electrical power system, the data comprising at least one of current signals and voltage signals. Further, the method comprises detecting (a plurality of) anomalies in said data and extracting features from (each of) said anomalies. Further the method comprises steps of identifying patterns (e.g. occurrence, magnitude or any other pattern) among said (plurality of) anomalies and classifying said anomalies based on said patterns so to sort (each) anomalies into classes (in some aspects, the patterns may be identified after classification). Moreover, the method comprises identifying anomalies, based on said extracted features, being correlative to conductor faults causing failure. Furthermore, the method comprises the steps of providing a prediction indicative of when at least one upcoming anomaly of a specific class will occur and determining, based on said prediction, a likelihood of that at least one of said upcoming anomalies causes failure in said electrical power system. Additionally, the method comprises the step of providing information of said prediction for being accessible to a user interface. In some aspects, the prediction may be accessible if said likelihood is above a pre-determined threshold/in response to said likelihood being above a pre-determined threshold. The threshold may be a specific severity level threshold or a specific likelihood percentage.

An advantage of the method is that it provides an accurate prediction on when a failure may occur. Thus, the method may efficiently and accurately predict which upcoming anomaly will cause failure in the system. Thus, maintenance of the system could be timely planned.

Further, there is an advantage in the system in that patterns are detected (solely) between identified anomalies. Hence, the other data, not being anomalies may be overlooked in the step of identifying patterns. This allow for a more efficient forecasting as a large amount of data may be disregarded. Additionally, identifying specific anomalies that may cause failure to the system enable corrective measures to be easier to apply as specific harmful anomalies are identified.

The term “predicting” herein may be interchanged with forecasting. The term conductor may refer to wires, cables, switches or any other conducting element connected to, or part of an electric power system. Hence, the term conductor may refer to any conducting element of an electric power system that may cause the electric power system to fail at a future point in time. Conductor faults may refer to physical defects or any other type of fault affecting a conductor.

The phrase “causing failure” may refer to that the faults, at a future point in time may cause failure to the electric power system.

In some aspects herein, the method may relate to a method for predicting upcoming faults causing failure in components of an electrical power system. The faults being any fault.

The data may be obtained in snapshots, further the data may be obtained from relays and PQ-meters or any other suitable electrical measuring device.

The components of electrical power systems herein comprise transmission and distribution components and conductors.

The classifications may be short circuit, unbalance, earth fault and cable fault.

The method may utilize at least one trained machine learning (ML) algorithm, preferably at least one of a Naïve Bayes Classifier, Support Vector Machine (SVM) Linear Regression, Logistic Regression, Artificial Neural Network (ANN), Decision Trees, Random Forests, K-Nearest Neighbours (KNN) and K-means clustering in the steps of classifying, identifying anomalies, and providing a prediction. It should be noted that ANN comprises (i) Multi-layer perceptron (MLP), (ii) Recurrent Neural Network, including Long-short term memory and Gated recurrent unit, (iii) Convolutional Neural Networks, and any combination thereof. Hence, each step of the method may be performed by utilizing a trained machine learning algorithm.

An advantage of utilizing a trained machine learning algorithm in the mentioned method steps is that a more accurate prediction could be provided. The machine learning algorithm is able to predict how anomalies over time evolves into failure.

The ML algorithm may identify anomalies based on specific snapshots of data, in which said ML algorithm, identifies irregular events in said data. The anomalies may be defined based on thresholds, i.e. an anomaly may in aspects herein be identified based on a probability on that an irregular event is an anomaly. Thus, a threshold may be set so that if a potential anomaly/irregular event has a probability below a threshold said event may not be identified as an anomaly. The threshold may be set by a user or the ML algorithm.

Accordingly, the trained machine learning algorithm may, based on extracted features and trained learning data, not only predict upcoming anomalies, but also predict when an upcoming anomaly/which anomaly will cause failure. However, for the prediction, anomalies being correlated to failure are of interest.

The extracted features may comprise at least one of harmonic content, frequency deviations, phase shift, jumps, amplitude, time of occurrence, root mean square (RMS), duration, admittance, resistance, inductance, impedance, active power and reactive power, normalized voltage signals and normalized current signals.

The step of classifying may further comprise one of, preferably all of, determining a fault direction of each anomaly relative to a measurement location associated to said anomaly. Further, the step of classifying may comprise estimating a distance of said anomaly relative said measurement location and determining a location of said anomaly within said electrical power system, based on said fault direction and distance estimation.

By obtaining fault direction, distance and location of anomalies, the method may advantageously, in the step of identifying anomalies, based on said extracted features being correlative to conductor faults causing failure; Disregard/filter out/prioritize irrelevant/relevant anomalies, i.e. anomalies that may stem from a location which is not correlated to failure or the system of electrical components thereof can be disregarded. Also, by determining the location, maintenance of the system is simplified based on that a user/operator can derive the location of anomalies.

In some aspects herein, the location is determined based on a known grid-topology or an estimated grid-topology of said electrical power system. Thus, allowing for a more rapid location estimation. The location estimation may be performed rule-based or based on the trained machine learning algorithm.

In some aspects, the method may comprise the step of determining a root cause of the identified anomalies being correlative to conductor faults causing failure, wherein the root cause is determined based on said patterns, or based on said patterns and said classes. In some aspects, the patterns may be (e.g. by the trained ML algorithm) compared to historic patterns which cause failure in said system, in which the cause of failure is known. Based on the historic patterns, the root cause may be determined. For instance, a root cause may be environmental conditions (thunder, over-grown vegetations or any other environmental condition) or hardware defects. The root cause may be provided as information for a user in the method step of providing information.

In other aspects herein, the (by e.g., the ML algorithm) method may further comprise the step of providing (for the user) data of at least one feature each identified anomaly correlative to conductor failure relate to/is associated with. Data may be e.g. at least one of type of feature, magnitude, occurrence or any other type of data.

The step of providing information may comprise providing a priority scheme/rank indicative of an extent each anomalies contribute to said prediction. The priority scheme may be derived by said machine learning algorithm in the step of providing a prediction.

Features may be harmonic content, frequency deviations, phase shift, jumps, amplitude, time of occurrence, root mean square (RMS), duration, impedance, active power and reactive power, normalized voltage signals, normalized current signals or any other feature.

An advantage of this is that a user may then provide countermeasures that may suppress the anomaly without necessarily solving the root cause.

The step of providing information may comprise an estimation of when said outage will occur, data of the anomaly causing the failure and location of the failure within said electrical power system.

Moreover, the prediction may be performed for a prediction horizon being from milliseconds, seconds, an hour, up to a month, or 2-3 months or 3-6 months.

Thus, providing the advantage of allowing for a long-term prediction thereby being able to provide maintenance timely.

In some aspects herein, the method is directed to a method for predicting upcoming cable faults causing failure in components of an electrical power system, specifically for cables for transmission and distribution.

In other aspects herein, the method is directed to a method for predicting upcoming wire faults in components of an electrical power system, the wire faults may be winding wire faults, e.g. stator winding wire faults, preferably winding insulation faults. The method may predict upcoming wire faults caused by degrading insulation material (e.g. sheathing material covering conductors) in said electrical power system or components thereof. Degrading of insulation material may occur due to electrical stress caused by switching surges placing the insulation of power cables/wires under high electrical stress.

Such data may be obtained by electrical measurement devices directed to measuring anomalies and provide it as wave shaped input for utilization in the method herein.

used to identify anomalies. The filtering may be machine learning based, so that a machine learning component is directed to filtering the correct amount of noise based on a trained learning algorithm that stores patterns from previous training data.

Consequently, in other aspects herein, the method may be directed to predicting upcoming cable faults causing failure in components of an electrical power system, such as causing failure in components of a power grid. The cables may be transmission and distribution cables. It should be noted that the method steps herein may be performed in different orders and may be varied within the knowledge of a skilled person and are therefore not bound to the order as disclosed herein. Moreover, method steps herein may be performed in parallel (specifically steps of identifying patterns, classifying into classes and identifying anomalies being correlative to conductor faults causing failure).

There is also provided a computer-readable storage medium storing one or more programs configured to be executed by one or more control circuitry of an electronic device, the one or more programs including instructions for performing the method according to any aspect herein.

Further, there is provided an electronic device, comprising one or more control circuitry and memory devices storing one or more programs configured to be executed by the one or more control circuitry, the one or more programs including instructions for performing the method herein. In some aspects, the electronic device may be an electrical power system.

### BRIEF DESCRIPTION OF THE DRAWINGS

In the following the disclosure will be described in a non-limiting way and in more detail with reference to exemplary embodiments illustrated in the enclosed drawings, in which:

FIG. 1 illustrates a flow chart of a computer-implemented method (100) for predicting upcoming conductor faults causing failure in components of an electrical power system in accordance with aspects herein;

FIG. 2 illustrates a diagram that shows captured current signals and the output of a model which identifies anomalous segments of the waveform of the signals;

FIG. 3 illustrates an exemplary schematic grid topology;

FIG. 4 illustrates an electronic device in accordance with some aspects of the present disclosure;

FIG. 5A illustrates a simulation that depicts the accuracy of the method in classifying anomalies;

FIG. 5B illustrates in the form of a graph priority scheme of anomalies contributing to forecasting probability;

FIG. 6 illustrates a user interface containing information of forecasting explainability for anomalies;

FIG. 7 illustrates feature group importance on forecasting based on corresponding phases;

FIG. 8 illustrates a time period that illustrates the method step of determining, based on a prediction, a likelihood of that at least one upcoming anomaly causes failure in an electrical power system;

FIG. 9 illustrates schematically the method in accordance with aspects herein for a disclosing purpose.

### DETAILED DESCRIPTION

In the following detailed description, some aspects of the present disclosure will be described. However, it is to be understood that features of the different aspects are exchangeable between the embodiments and may be combined in different ways, unless anything else is specifically indicated. Even though in the following description, numerous specific details are set forth to provide a more thorough understanding of the provided device and method, it will be apparent to one skilled in the art that the device and method may be realized without these details. In other instances, well known constructions or functions are not described in detail, so as not to obscure the present disclosure.

In the following description of example embodiments, the same reference numerals denote the same or similar components.

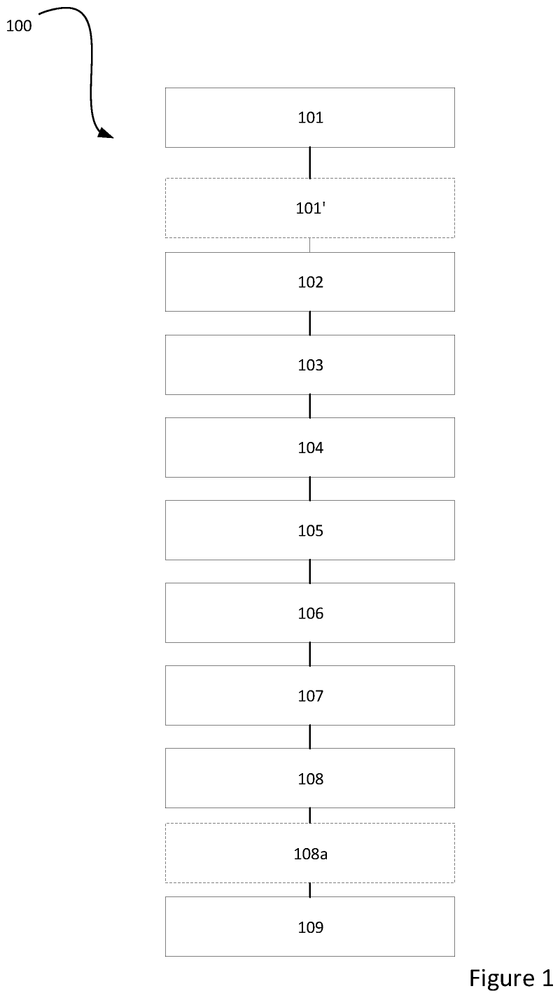

FIG. 1 schematically illustrates in the form of a flowchart, a method 100 for predicting upcoming conductor faults causing failure in components of an electrical power system the method 100 comprising the steps of: obtaining data 101 from said components of said electrical power system, the data comprising at least one of current signals and voltage signals. The data may be obtained continuously. Further, the method comprises detecting anomalies 102 in said data and extracting features 103 from said anomalies. Components of an electrical power system may be cables, generators, relays, insulations, overhead lines.

Further, the method comprises identifying patterns 104 among/between said anomalies and classifying 105 said anomalies based on said patterns so to sort anomalies into classes. Moreover, the method comprises identifying anomalies 106, based on said extracted features, being correlative to conductor faults causing failure. Thus, in step 104, each one of the anomalies may be compared to identify patterns among the anomalies.

Additionally, the method 100 provides 107 a prediction indicative of when at least one upcoming anomaly of a specific class (of one of the mentioned classes) will occur. Furthermore, the method 100 is directed to determining 108, based on said prediction, a likelihood of that at least one of said upcoming anomalies causes failure in said electrical power system and provides 109 information of said prediction accessible to a user if said likelihood is above a pre-determined threshold.

FIG. 1 further illustrates that prior the step of detecting anomalies 102 the method 100 may comprise the step of filtering 101′ frequency components above and/or below specific frequency ranges. E.g. above/below specific amplitudes. This may be performed by utilizing a frequency filter device, preferably a band-pass filter. The term “electrical power system” herein may refer to any network of electrical components used to supply (generate), transmit, distribute, and consume electric power.

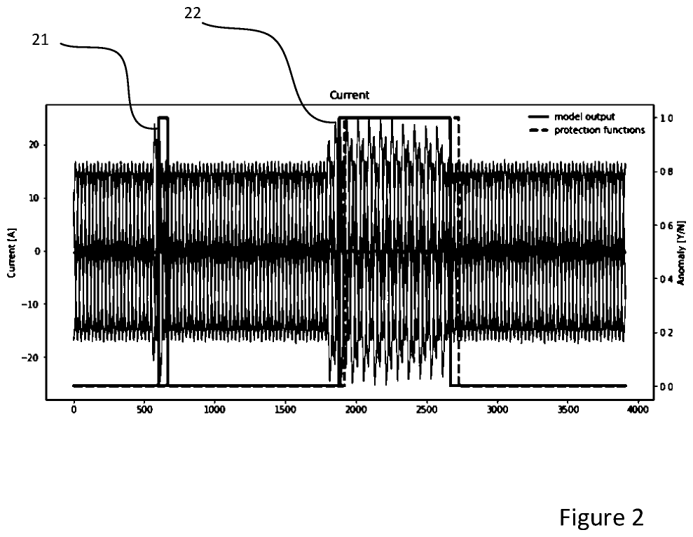

FIG. 2 illustrates an example of obtained current signals from a component of an electrical power system. Further reference numerals 21 and 22 illustrate portions in the graph containing anomalies. Hence, the anomalies may be deviations from a common pattern.

Accordingly, the method 100 may identify patterns among anomalies (e.g. the anomalies 21, 22 in FIG. 2). The method 100 may based on patterns classify the anomalies. Classes may be short circuit, unbalance, earth fault (e.g. transient, low ohmic, high ohmic, intermittent), cable faults or any other suitable classifications. Other classifications may be sag, swell, transient, interruption, harmonics, frequency deviations, flicker. In some aspects the classification may be a binary classification. Classification may be performed by a trained learning algorithm based on previous training.

It should be noted that the step 102 is directed to detecting anomalies as such. Whereas step 106 is directed to identifying of anomalies being correlated to upcoming faults. Accordingly, method step 106, may be based on the extracted features, but also, in some aspects herein, based upon the specific class in which anomalies are clustered into. In some aspects herein, the phrase “upcoming faults” may refer to upcoming faults within a specific time-period, or in any future time-period.

The prediction step 107 of the method 100 may predict how anomalies evolve over time, e.g. a time period of from milliseconds, seconds, an hour to 3 months—and when an upcoming anomaly will cause failure. The prediction may comprise number, amplitude, time of occurrence of anomalies in future cycles. The prediction may therefore comprise estimation of remaining life cycle of electric components of electric power systems.

It should be noted that specifically, the steps of classifying 105, identifying 106 and providing 109 may utilize at least one trained machine learning algorithm. The machine learning algorithm comprise at least one of a Naïve Bayes Classifier, Support Vector Machine, SVM, Linear Regression, Logistic Regression, Artificial Neural Network, ANN, Decision Trees, Random Forests, K-Nearest Neighbors, KNN and K-means clustering.

Further, the extracted features may comprise at least one of harmonic content, frequency deviations, phase shift, jumps, amplitude, time of occurrence, root mean square (RMS), duration, impedance, active power and reactive power, normalized voltage and current signals.

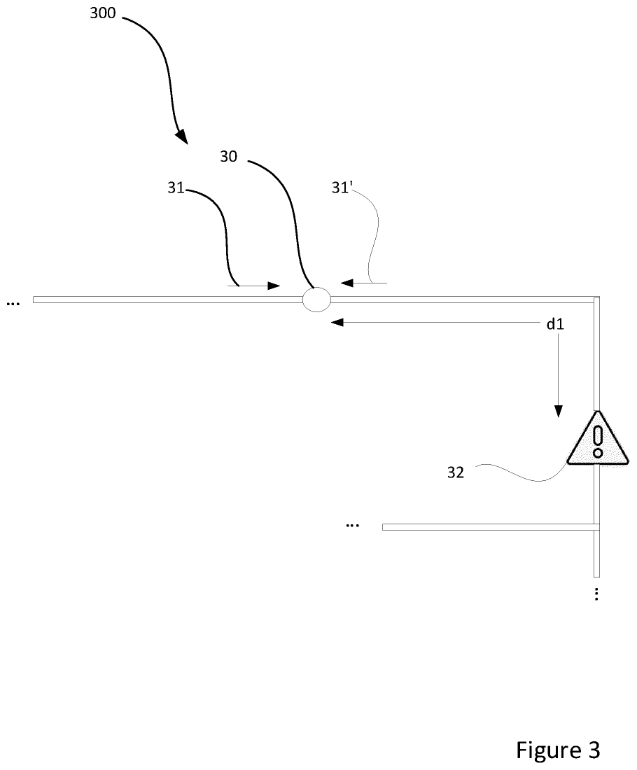

FIG. 3 schematically in an exemplary manner illustrates a part of a grid topology 100 of an electrical power system, and specifically illustrates that the step of classifying 104 (which is shown schematically in FIG. 1) may further comprise:
determining a fault direction 31, 31′ of each anomaly relative to a (at least one) measurement location 30 associated to said anomaly (e.g. from which direction the anomaly stems from viewed from the measurement location 30);
estimating a distance d1 of said anomaly relative said measurement location 30;
determining a location 32 of said anomaly within said electrical power system, based on said fault direction and distance estimation.

Thus, FIG. 3 illustrates a part of a grid topology 300 that shows, based on a specific (e.g. known) measurement location 30 of an anomaly, a fault direction 31, 31′ may be determined. Fault direction may refer to which direction 31, 31′ the anomaly stems from. In FIG. 3, the true fault direction is denoted 31′. Thus, based on the estimated fault direction and specific voltage and/or current values, a distance of said anomaly could be estimated which in turn allows location estimation so to derive the location 32 of said anomaly. Thus, specific components of the electric power system being under the risk of failure may be identified. In other words, based on the above, the location 32 may be a location in an electrical power system in which an upcoming conductor fault causing failure in a specific component of an electrical power system/or the electrical power system as such, may occur. It should be noted that in some aspects herein, based on the step of classifying 105, the method may determine a type of electrical component that an anomaly originate from. Thus, the determining location may additionally be based on said determined electrical component. E.g. the step of extracting features may be performed after classification. In other words, the method may determine a location 32 of said anomaly within said electrical power system, based on said fault direction, distance estimation and type of electrical component said anomaly originates from, wherein the type of electrical component is determined in the step of classification.

The wire faults may be wire faults caused by degrading insulation material in said electrical power system.

The step of providing information 109 may comprise an estimation of when said outage will occur, data of the anomaly causing the failure and location of the failure within said electrical power system. Further, in some aspects herein the information will be transmitted as a notification/warning to a user/operator of the electric power system. In some aspects, the information may be provided so to be visually emphasized for a user/operator.

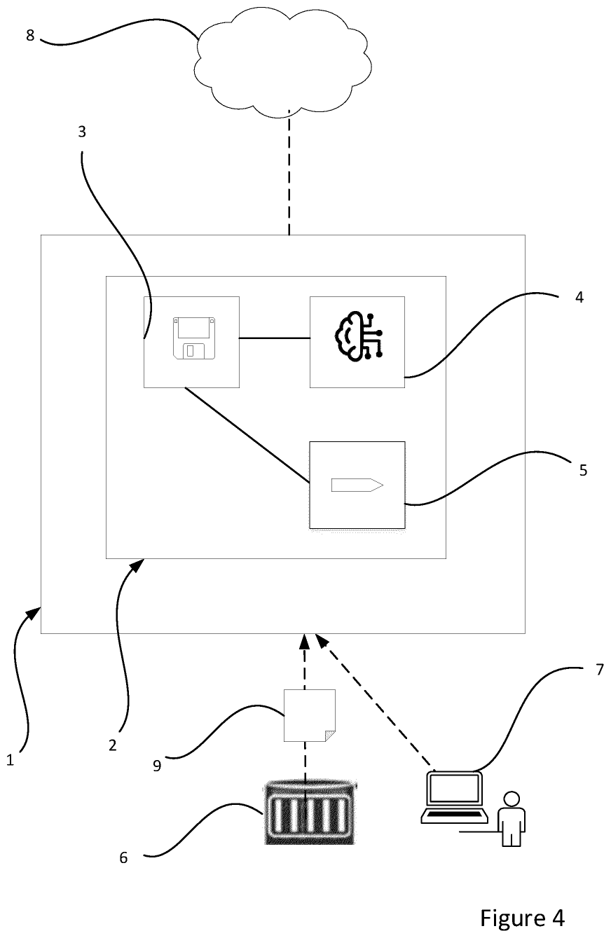

FIG. 4 illustrates an electronic device 1, comprising one or more control circuitry 2 and memory devices 3 storing one or more programs configured to be executed by the one or more control circuitry 2, the one or more programs including instructions for performing the method 100 of any aspect herein for predicting upcoming conductor faults causing failure in components of an electrical power system (or electrical power system as such).

The at least one memory device 3 may comprise any form of volatile or non-volatile computer readable memory including, without limitation, persistent storage, solid-state memory, remotely mounted memory, magnetic media, optical media, random access memory (RAM), read-only memory (ROM), mass storage media (for example, a hard disk), removable storage media (for example, a flash drive, a Compact Disk (CD) or a Digital Video Disk (DVD)), and/or any other volatile or non-volatile, non-transitory device readable and/or computer-executable memory devices that store information, data, and/or instructions that may be used.

The control circuitry 2 may be arranged to run instruction sets in the memory devices 3 for operating the method 100. The control circuitry 2 may be any suitable type such as a microprocessor, digital signal processor (DSP), ASIC (Application Specific Integrated Circuit), FPGA (Field Programmable Gate Array), Graphics processing unit (GPU) or a combination of these, or other similar processing means arranged to run instruction sets. The computer readable storage medium may be of non-volatile and/or volatile type and transitory or non-transitory type; for instance RAM, EEPROM, flash disk and so on. It should be noted that the memory unit 3 may be integrated with the control circuitry 2. The control circuitry 2 may comprise an input/output interface 5 and a communication interface of any suitable type such as Ethernet, I2C bus, RS232, CAN bus, wireless communication technology such as IEEE 802.11 based or cellular based technologies, or other communication protocols depending on application. The communication interface may be used for receiving signals, software updates, and instruction messages. Furthermore, the communication interface may be used to communicate results, messages, status reports and similar to external devices and control units such as a control station or servers via a network, e.g. via public or private networks.

Each memory device 3 may also store data that can be retrieved, manipulated, created, or stored by the control circuitry 2. The data may include, for instance, local updates, parameters, training data, extracted features, anomalies, patterns, classes and data of voltage and current. As shown in FIG. 4, the control circuitry may comprise a machine learning component/engine 4 arranged to store and process previous data, real-time data, predicted data (i.e. the trained learning algorithms), trained learning algorithms (and/or the models, components, data utilized in said trained learning algorithms). However, in some aspects, the trained machine learning algorithm and machine learning component 4 may be stored in a cloud computing device 8 accessible by the control circuitry 2. FIG. 4 illustrates that in some aspects, the control circuitry 2 may comprise a machine learning component 4, that based on data from the memory device 2, may implement at least one trained learning algorithm. The data can also be stored in one or more databases or cloud computing devices 8. The one or more databases can be connected to the electronic device 1 through a communication network.

FIG. 4 further illustrates that data 9 may be obtained from an electrical component 6 of an electric power system in line with method step 101 as illustrated in FIG. 1. Moreover, FIG. 4 further illustrates that a user/operator 7 may be receiving information, at a respective electronic device thereof, provided by said electronic device. Information may be prediction of when at least one upcoming anomaly of a specific class will occur, and wherein said upcoming anomaly have a likelihood above a pre-determined threshold of causing failure in said electrical power system at a specific point in time. The specific point in time of when said failure will occur may also be provided by said electronic device 1.

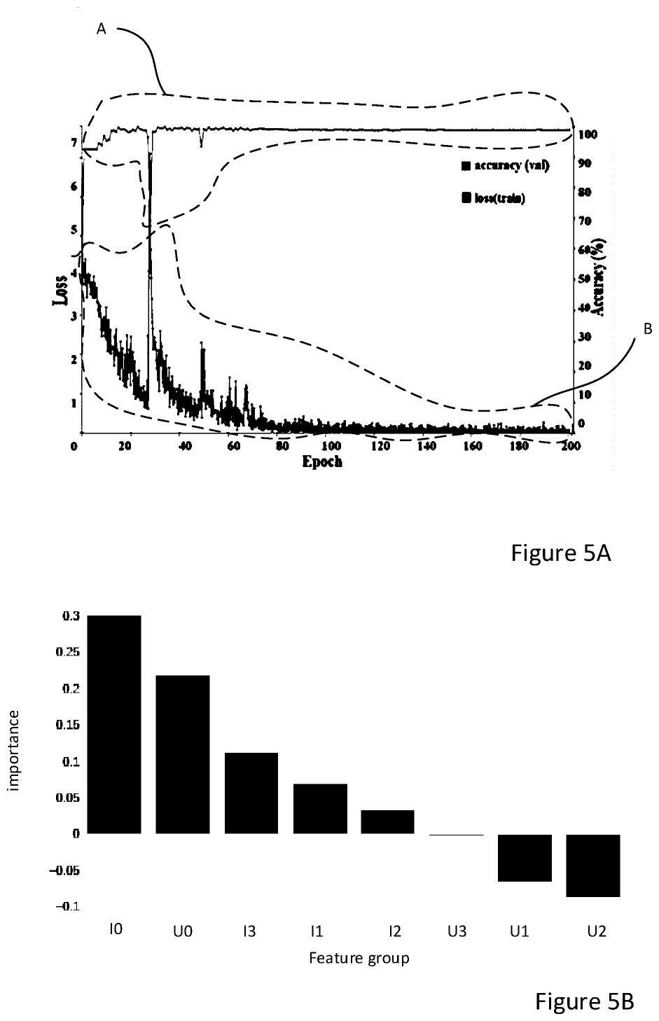

FIG. 5A-5B and FIG. 6-9 show the performance and aspects of the method 100 and electronic device 1 as disclosed herein. The purpose of the FIGS. 5A-8 is to further describe the disclosure as presented herein accompanied with advantages thereof. It should be noted that the simulations/test results are based on aspects herein for a disclosing purpose, however it is not limited to said aspects and may be varied within the present disclosure.

FIG. 5A illustrates a graph showing that the method 100 and device 1 herein demonstrates a 99% accuracy (shown by the graph A) of classifying anomalies. Graph B in FIG. 5A shows loss during training of the trained machine learning algorithm. Further, FIG. 5B illustrates a graph having a priority scheme indicative of the extent each anomaly contributes to the prediction. Anomaly in 10 in FIG. 5B is the anomaly contributing to the largest extent to the prediction.

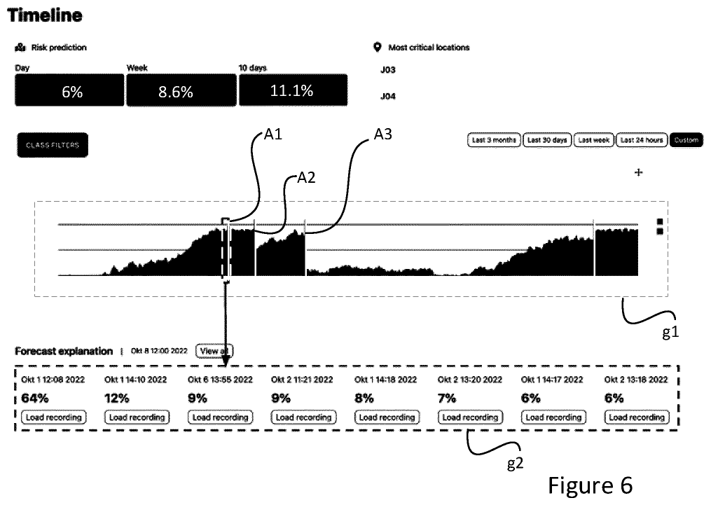

Similarly, FIG. 6 illustrates a user interface for a user depicting forecasting explainability as. The method and device herein may provide information to said user by said user interface. FIG. 6 illustrates that each forecasting probability A1 for prediction of fault occurrences A2 and A3 as illustrated in FIG. 6 is depicted at said user interface for a user. FIG. 6 illustrates that the method and device herein may provide predictions as illustrated in graph g1 in FIG. 6. As illustrated, there are a plurality of anomalies A1-A3 in the prediction. Moreover, FIG. 6 illustrates in an exemplary manner the anomalies a that are contributing the most to the forecasting of anomaly A2 as illustrated in graph g2.

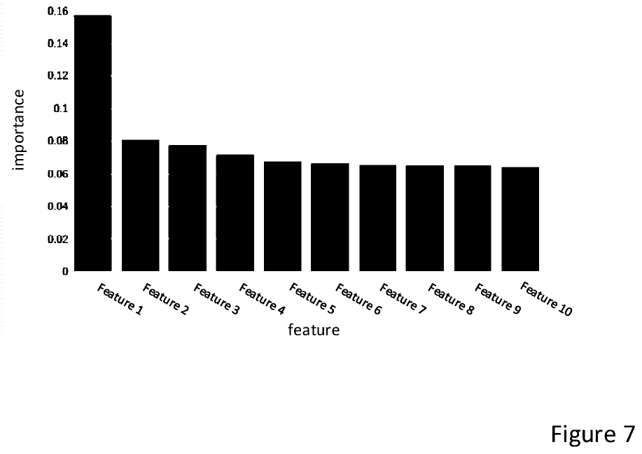

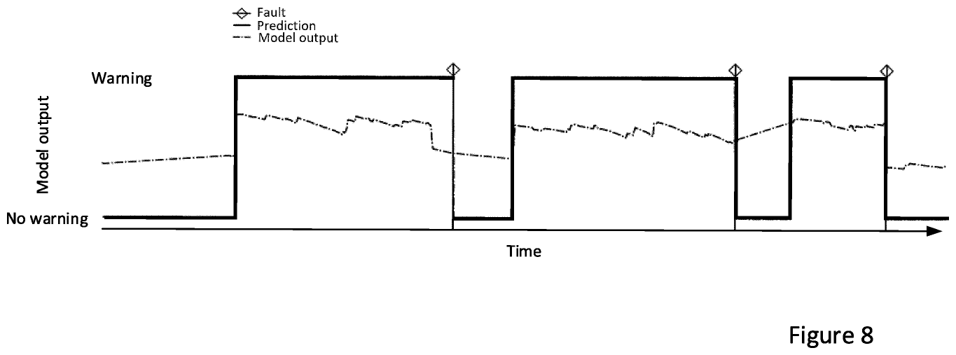

FIG. 7 illustrates in the form of a graph feature group importance on forecasting based on corresponding phases. Thus, the method may provide data of at least one feature each identified anomaly correlative to conductor failure relate to and also the extent of contribution said at least one feature has to said anomaly. In FIG. 7, feature 1 contributes the most to the prediction. FIG. 8 illustrates schematically, over a time period, a simulation of the steps of providing 107 a prediction indicative of when at least one upcoming anomaly of a specific class will occur.

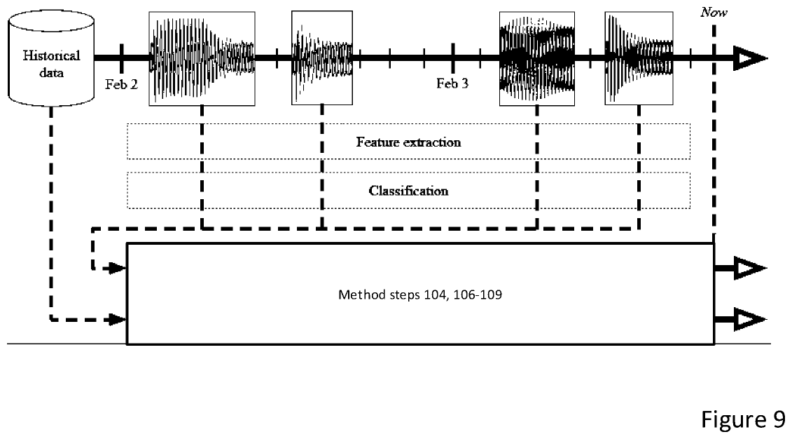

Further, FIG. 8 also shows that information is provided 109 in the form of a warning. Thus, in more detail, FIG. 8 illustrates a raw output of a trained machine learning algorithm (see dotted lines in FIG. 8) and a binary prediction as a result of the determining step 108 in any aspect of the method 100 herein. Accordingly, the solid line illustrates that based on the prediction of the trained machine learning algorithm, a warning should be provided based on that a likelihood of that at least one of said upcoming anomalies causes failure in said electrical power system exceeds a pre-determined threshold. Thereby, the warning is provided in time prior to the actual fault, as shown in FIG. 9.

FIG. 9 illustrates in an exemplary manner the method 100 performed over a time period, where it is illustrated that based on data (historical and live data) the method may continuously perform feature extraction and classification. Moreover, the method 100 may be based on the extraction and classification perform the method steps of 104, 106-109. The method may during the step of identifying patterns, identify patterns based on a recent time window and also identify patterns based on cyclic and periodic trends obtained from historical data.

1. A computer-implemented method for predicting upcoming faults in conductors causing failure in components of an electrical power system, the method comprising:
obtaining data from said components of said electrical power system, the data comprising at least one of current signals and voltage signals;
detecting anomalies in said data;
extracting features from said anomalies;
identifying patterns among said anomalies;
classifying said anomalies based on said patterns so to sort anomalies into classes;
identifying anomalies, based on said extracted features, being correlative to conductor faults causing failure;
providing a prediction indicative of when at least one upcoming anomaly of a specific class will occur;
determining, based on said prediction, a likelihood of that at least one of said upcoming anomalies causes failure in said electrical power system; and
providing information of said prediction accessible to a user.

2. The method according to claim 1, wherein the method utilizes at least one trained machine learning algorithm.

3. The method according to claim 2, wherein the at least one trained machine learning algorithm utilizes at least one of a Naïve Bayes Classifier, Support Vector Machine, SVM, Linear Regression, Logistic Regression, Artificial Neural Network, ANN, Decision Trees, Random Forests, K-Nearest Neighbors, KNN or K-means clustering for of classifying, identifying and providing.

4. The method according to claim 1, wherein the extracted features comprises at least one of harmonic content, frequency deviations, phase shift and jumps, amplitude, time of occurrence, root mean square, RMS, duration, impedance, admittance, resistance, inductance, active power and reactive power, or normalized voltage and current signals.

5. The method according to claim 1, wherein classifying further comprises:
determining a fault direction of each anomaly relative to a measurement location associated to said anomaly;
estimating a distance of said anomaly relative said measurement location; and
determining a location of said anomaly within said electrical power system, based on said fault direction and distance estimation.

6. The method according to claim 5, wherein said location is determined based on a known grid-topology or an estimated grid-topology of said electrical power system.

7. The method according to claim 1, wherein the conductor faults are conductor faults caused by degrading insulation material in said electrical power system.

8. The method according to claim 1, wherein providing information comprises an estimation of when an outage will occur, data of the at least one upcoming anomaly causing the failure and location of the failure within said electrical power system.

9. The method according to claim 1, wherein the prediction is performed for a prediction horizon being up to a month, 2-3 months or 3-6 months.

10. The method according to claim 1, further comprising:
determining a root cause of the identified anomalies being correlative to conductor faults causing failure, wherein the root cause is determined based on said patterns.

11. The method according to claim 1, wherein providing information comprises:
providing data of at least one feature each identified anomaly correlative to conductor failure relate to.

12. The method according to claim 11, wherein providing information comprises:
providing a priority scheme indicative of an extent each anomalies contribute to said prediction.

13. A non-transitory computer-readable storage medium storing one or more programs configured to be executed by one or more control circuitry of an electronic device to perform the method of claim 1.

14. An electronic device, comprising one or more control circuitry and memory devices storing one or more programs configured to be executed by the one or more control circuitry to performs the method of claim 1.
